(19) United States
(12) Patent Application Publication
(10) Pub. No.: US 2024/0053513 A1
(43) Pub. Date: Feb. 15, 2024

(54) METHOD FOR FABRICATING METASURFACE LENS AND METASURFACE LENS

(71) Applicant: Shphotonics Ltd, Suzhou (CN)

(72) Inventors: Yuhao YAN, Suzhou (CN); Shanfeng QIU, Suzhou (CN); Lei SUN, Suzhou (CN)

(21) Appl. No.: 18/356,842

(22) Filed: Jul. 21, 2023

(30) Foreign Application Priority Data
Aug. 15, 2022 (CN) 202210973981.2

(51) Int. Cl. G02B 3/00; G02B 1/00; G02B 27/00

(52) U.S. Cl. CPC G02B 3/0031; G02B 1/002; G02B 27/0068; G02B 2207/101

(57) ABSTRACT

A metasurface lens fabrication method includes obtaining a metasurface lens image, dividing the metasurface lens image to obtain at least two sub-images and one or more masks each corresponding to one or more of the at least two sub-images, performing image transfer on a first wafer through the at least two sub-images and the one or more masks to obtain a second wafer with the metasurface lens image, and performing lens fabrication processing on the second wafer to obtain the metasurface lens.

### CROSS-REFERENCE TO RELATED APPLICATION

This application claims priority to Chinese Application No. 202210973981.2, filed on Aug. 15, 2022, the entire content of which is incorporated herein by reference.

### TECHNICAL FIELD

The present disclosure relates to the metasurface lens technology field and, in particular, to a method for fabricating a metasurface lens and the metasurface lens.

### BACKGROUND

Metasurface lens is an ultra-thin two-dimensional array plane including a series of sub-wavelength artificial microstructures. The metasurface lens has the characteristics of relatively simple fabrication, relatively low loss, small volume, and small thickness. The metasurface lens can effectively control various aspects, such as amplitude, phase, propagation mode, and polarization state, of an electromagnetic wave. Compared with a conventional lens such as a conventional multi-piece objective lens or a self-focusing lens, the metasurface lens has unique advantages. The metasurface lens is much smaller in size, thickness, and weight than other types of lenses, while having a relatively large numerical aperture.

In a metasurface lens fabrication process, an Electron Beam Lithography (EBL) system and a step-scanning lithography system are generally used. However, for a large-scale pattern, the EBL can be less efficient and have a high cost.

The step-scanning lithography system is a hybrid system that combines a scanning projection lithography machine and a step repeating lithography machine by using a reduction lens to scan a large exposure field image onto a part of a wafer. A standard exposure size of the lithography machine is 26 mm×33 mm. However, although the wafer for fabricating the metasurface lens can satisfy the size requirement, the maximum exposure field of the lithography machine cannot achieve the requirement for fabricating the large-scale pattern metasurface lens. Due to the limitation of the maximum exposure field of the lithography machine and the nano-imprinting apparatus, one whole large-scale metasurface lens feature image cannot be transferred to the wafer through one time of exposure or imprinting. Thus, metasurface lens sub-patterns obtained by performing a plurality of times of exposure and imprinting are cut off. The cut modules can be spliced according to the design of the surface of the metasurface lens. A splicing error is relatively large for such splicing manner, which reduces the optical performance of the spliced metasurface lens.

Thus, a method for fabricating the metasurface lens satisfying the optical performance with high efficiency and low cost needs to be developed.

### SUMMARY

Embodiments of the present disclosure provide a metasurface lens fabrication method. The method includes obtaining a metasurface lens image, dividing the metasurface lens image to obtain at least two sub-images and one or more masks each corresponding to one or more of the at least two sub-images, performing image transfer on a first wafer through the at least two sub-images and the one or more masks to obtain a second wafer with the metasurface lens image, and performing lens fabrication processing on the second wafer to obtain the metasurface lens.

### BRIEF DESCRIPTION OF THE DRAWINGS

FIG. 1 is a schematic flowchart of a method for fabricating a metasurface lens according to some embodiments of the present disclosure.

FIG. 2 is a schematic diagram of an exposure pattern of a metasurface lens according to some embodiments of the present disclosure.

FIG. 3 is a schematic diagram showing a plurality of sub-modules obtained by dividing a pattern after performing software processing according to some embodiments of the present disclosure.

FIG. 4 is a schematic diagram showing a photolithography or nano-imprinting mask fabricated according to a software processing result according to some embodiments of the present disclosure.

FIG. 5 is a schematic diagram showing pattern transfer of a mask on a wafer using a step photolithography machine or nano-imprinting according to some embodiments of the present disclosure.

FIG. 6 is a schematic diagram showing a plurality of spliced sub-modules obtained by dividing a pattern that is transferred to a wafer according to some embodiments of the present disclosure.

FIG. 7 is a schematic flowchart showing splicing a complete metasurface lens on a spliced substrate using an active alignment (AA) process according to some embodiments of the present disclosure.

FIG. 8 is a schematic diagram showing a complete metasurface lens spliced according to a design graphics using a cut sub-modules after division according to some embodiments of the present disclosure.

FIG. 9 is a schematic diagram showing a designed function of a metasurface lens according to some embodiments of the present disclosure.

FIG. 10 is a schematic diagram of a spliced metasurface lens according to some embodiments of the present disclosure.

FIG. 11 is a schematic diagram showing a light source modulation effect by calibrating a metasurface lens by an assembly formed by a compensation lens that is fabricated for the spliced metasurface lens according to some embodiments of the present disclosure.

FIG. 12 is a schematic diagram showing metasurface lens pattern processing and division according to some embodiments of the present disclosure.

FIG. 13 is a schematic diagram showing pattern transfer template fabrication according to some embodiments of the present disclosure.

FIG. 14 is a schematic diagram showing a single design pattern transfer process during fabrication according to some embodiments of the present disclosure.

FIG. 15 is a schematic diagram showing a mass fabrication process on a whole wafer according to some embodiments of the present disclosure.

### DETAILED DESCRIPTION OF THE EMBODIMENTS

In the following, some example embodiments are described. As those skilled in the art would recognize, the described embodiments can be modified in various manners, all without departing from the spirit or scope of the present disclosure. Accordingly, the drawings and descriptions are illustrative in nature and not limiting.

In the present disclosure, terms such as “first,” “second,” and “third” can be used to describe various elements, components, regions, layers, and/or parts. However, these elements, components, regions, layers, and/or parts should not be limited by these terms. These terms are only used to distinguish one element, component, region, layer, or part from another element, component, region, layer, or layer. Therefore, a first element, component, region, layer, or part discussed below can also be referred to as a second element, component, region, layer, or part, which does not constitute a departure from the teachings of the present disclosure.

A term specifying a relative spatial relationship, such as “below,” “beneath,” “lower,” “under,” “above,” or “higher,” can be used in the disclosure to describe the relationship of one or more elements or features relative to other one or more elements or features as illustrated in the drawings. These relative spatial terms are intended to also encompass different orientations of the device in use or operation in addition to the orientation shown in the drawings. For example, if the device in a drawing is turned over, an element described as “beneath,” “below,” or “under” another element or feature would then be “above” the other element or feature. Therefore, an example term such as “beneath” or “under” can encompass both above and below. Further, a term such as “before,” “in front of,” “after,” or “subsequently” can similarly be used, for example, to indicate the order in which light passes through the elements. A device can be oriented otherwise (e.g., being rotated by 90 degrees or being at another orientation) while the relative spatial terms used herein still apply. In addition, when a layer is referred to as being “between” two layers, it can be the only layer between the two layers, or there can be one or more intervening layers. In this disclosure, if a light beam encounters a first element and then reaches a second element, the second element is referred to as being downstream the first element or downstream the first element in an optical path, and correspondingly the first element is referred to as being upstream the second element or upstream the second element in the optical path.

Terminology used in the disclosure is for the purpose of describing the embodiments only and is not intended to limit the present disclosure. As used herein, the terms “a,” “an,” and “the” in the singular form are intended to also include the plural form, unless the context clearly indicates otherwise. Terms such as “comprising” and/or “including” specify the presence of stated features, entities, steps, operations, elements, and/or parts, but do not exclude the existence or addition of one or more other features, integers, steps, operations, elements, parts, and/or combinations thereof. As used herein, the term “and/or” includes any and all combinations of one or more of the listed items. The phrases “at least one of A and B” and “at least one of A or B” mean only A, only B, or both A and B.

When an element or layer is referred to as being “on,” “connected to,” “coupled to,” or “adjacent to” another element or layer, the element or layer can be directly on, directly connected to, directly coupled to, or directly adjacent to the other element or layer, or there can be one or more intervening elements or layers. In contrast, when an element or layer is referred to as being “directly on,” “directly connected to,” “directly coupled to,” or “directly adjacent to” another element or layer, then there is no intervening element or layer. “On” or “directly on” should not be interpreted as requiring that one layer completely covers the underlying layer.

In the disclosure, description is made with reference to schematic illustrations of example embodiments (and intermediate structures). As such, changes of the illustrated shapes, for example, as a result of manufacturing techniques and/or tolerances, can be expected. Thus, embodiments of the present disclosure should not be interpreted as being limited to the specific shapes of regions illustrated in the drawings, but are to include deviations in shapes that result, for example, from manufacturing. Therefore, the regions illustrated in the drawings are schematic and their shapes are not intended to illustrate the actual shapes of the regions of the device and are not intended to limit the scope of the present disclosure.

Unless otherwise defined, all terms (including technical and scientific terms) used herein have the same meaning as commonly understood by those of ordinary skill in the art to which this disclosure belongs. Terms such as those defined in commonly used dictionaries should be interpreted to have meanings consistent with their meanings in the relevant field and/or in the context of this disclosure, unless expressly defined otherwise herein.

As used herein, the term “substrate” can refer to the substrate of a diced wafer, or the substrate of an un-diced wafer. Similarly, the terms “chip” and “die” can be used interchangeably, unless such interchange would cause conflict. The term “layer” can include a thin film, and should not be interpreted to indicate a vertical or horizontal thickness, unless otherwise specified.

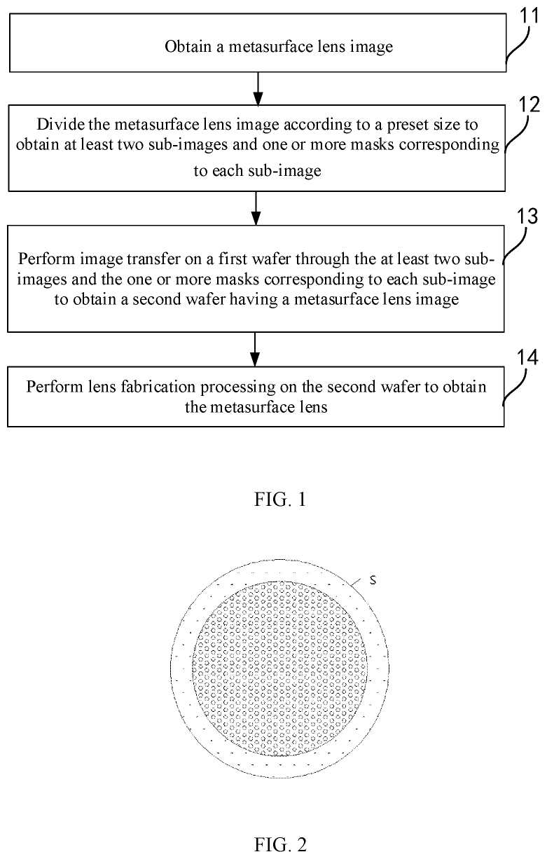

FIG. 1 is a schematic flowchart of a method for fabricating the metasurface lens according to some embodiments of the present disclosure. As shown in FIG. 1, the method includes the following processes.

At 11, a metasurface lens image (i.e., an image of a metasurface lens) is obtained.

At 12, the metasurface lens image is divided according to a preset size to obtain at least two sub-images and one or more masks each corresponding to one or more sub-images.

At 13, image transfer is performed on a first wafer through the at least two sub-images and the one or more masks to obtain a second wafer having a metasurface lens image.

At 14, lens fabrication processing is performed on the second wafer to obtain the metasurface lens.

In some embodiments, the metasurface lens image can be obtained. The metasurface lens image can be divided according to the preset size to obtain the at least two sub-images and the one or more masks corresponding to the sub-images. The image transfer can be performed on the first wafer through the at least two sub-images and the one or more masks to obtain the second wafer having the metasurface lens image. The lens fabrication processing can be performed on the second wafer to obtain the metasurface lens. The efficiency can be improved and the cost can be reduced, while the optical performance requirement being satisfied.

In some embodiments, process 12 can include dividing the metasurface lens image according to the preset size to obtain the at least two sub-images and fabricating the one or more masks corresponding to the sub-images according to the at least two sub-images. If two sub-images are same as each other, a mask fabricated according to the same image can be used as the mask corresponding to the two sub-images (which are the same image).

Fabricating one mask for the same images can reduce the manufacturing cost and improve the efficiency.

In some embodiments of the present disclosure, process 13 can include arranging the one or more masks according to the metasurface lens image to obtain an arranged image mask and performing the image transfer on the first wafer according to the arranged image mask to obtain the second wafer.

In some embodiments, if one mask corresponds to at least two identical sub-images, then during the image transfer for the first wafer, the image transfer is performed for the at least two identical sub-images through the mask corresponding to the at least two identical sub-images according to a preset order.

In some embodiments, during the image transfer using the mask corresponding to the at least two identical sub-images, if an angle deviation exists between the at least two identical sub-images, the mask corresponding to the at least two identical sub-images or the wafer is rotated, until the angle deviation is eliminated, and the image transfer can be performed according to the preset order. That is, if an angle deviation exists between a first sub-image and a second sub-image among the at least two identical sub-images and the preset order is that image transfer is to be performed first for the first sub-image and then for the second sub-image, then the mask or the wafer can be rotated by an angle corresponding to the angle deviation after image transfer is performed for the first image and before image transfer is performed for the second image.

In some embodiments of the present disclosure, process 14 can include performing developing, etching, cleaning, and/or coating on the second wafer to obtain a third wafer, dividing the third wafer according to a preset size to obtain at least two sub-wafers, and splicing the at least two sub-wafers according to the metasurface lens image to obtain the metasurface lens.

In some embodiments, splicing the at least two sub-wafers to obtain the metasurface lens can include splicing the at least two sub-wafers according to the metasurface lens image to obtain a spliced transition lens, measuring aberration of the transition lens and designing a compensation lens according to the aberration, and combining the compensation lens and the transition lens to obtain the metasurface lens.

In some embodiments, splicing the at least two sub-wafers to obtain the metasurface lens can include determining an optimal modulation transfer function of each two neighboring sub-wafers of the at least two sub-wafers through active alignment according to the metasurface lens image, and splicing the at least two sub-wafers according to the optimal modulation transfer function to obtain the metasurface lens.

FIG. 2 to FIG. 7 illustrate a method for fabricating a large-scale metasurface lens based on active alignment (AA) process according to some embodiments of the present disclosure. AA process is a process that during the assembling of each component, an apparatus applies light or electricity to synchronously test an assembled semi-finished product and performs AA according to a test result of the assembled semi-finished product, and then assemble two or more components. The AA technology can effectively reduce the assembly tolerance of the whole assembly to effectively improve the consistency of the camera product, which can be used to package a higher-order camera product. As shown in FIG. 2 to FIG. 7, the method includes the following processes.

At process one, image processing is performed on a design file of the large-scale metasurface lens pattern to extract areas with the same pattern, and divide the pattern into a plurality of sub-modules smaller than or equal to 26 mm×33 mm. Only one photolithography mask or nano-imprinting mask (both are also referred to as “image transfer mask”) is fabricated for repeated sub-modules. Image transfer masks are fabricated for other non-repeated pattern areas, respectively. One or more masks can be obtained at process one.

At process two, a mobile platform first moves to an initial image transfer position, and the mask corresponding to the current position fabricated in process one is used to perform exposure or imprinting. Imprinting is also image transfer. The software for splitting the exposure image can be developed by using suitable programming tool or pattern processing tool.

At process three, the mobile platform repeats process two at a next image transfer position to perform the image transfer at this position.

At process four, process three is repeated until the image transfer of the pattern of the mask is completed for the whole substrate.

At process five, the mask is switched or a mask pattern at a different position in the same mask is used, the mobile platform moves to a next exposure position to repeat process two to process four to complete the image transfer of the mask pattern for the whole substrate.

At process six, process five is repeated until the image transfer of all the sub-modules for slicing is completed.

At process seven, subsequent processes such as developing and etching are performed on the substrate on which the whole image transfer is completed to obtain sub-modules of the large-scale metasurface lens structure.

At process eight, the sub-modules of the metasurface lens on the substrate are cut to obtain a plurality of individual sub-modules.

At process nine, the cut sub-modules are spliced on a substrate (also referred to as “splicing substrate”) according to the pattern design. AA is performed during splicing. A combination mode of obtaining the optimal modulation transfer function between two neighboring sub-modules is determined. The Modulation Transfer Function (MTF) is a method for analyzing the image of the lens and an MTF imaging curve graph can be used as a technical reference for the imaging quality of the lens.

At process ten, process nine is repeated to splice the remaining sub-modules after AA until the whole metasurface lens is completed.

The present disclosure is further described in connection with the accompanying drawings and the method for fabricating large-scale metasurface lens based on AA.

In some embodiments, a step-scanning lithography system can be configured to fabricate the large-scale metasurface lens. In some other embodiments, a step nano-imprinting system can be configured to fabricate the large-scale metasurface lens.

In some embodiments, as shown in FIG. 2, circular area S is a designed metasurface lens pattern area. Circular area S is larger than an exposure field of view with an area of 26 mm×33 mm of the step lithography machine.

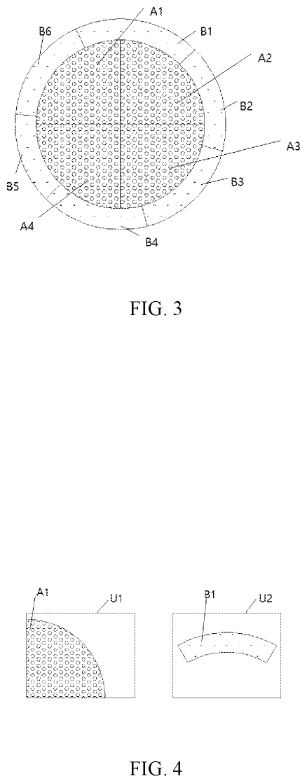

In some embodiments, as shown in FIG. 3, the image is divided into a plurality of sub-modules smaller than 26 mm×33 mm through software processing. A1, A2, A3, and A4 can include a same image. B1, B2, B3, B4, B5, and B6 can include a same image.

In some embodiments, as shown in FIG. 4, a lithography mask is fabricated by directly writing using electron beam lithography or machining according to a software processing result. If some sub-modules are identical, only one mask needs to be fabricated for these identical sub-modules. According to sizes of the sub-modules, images of a plurality of sub-modules can be designed on the same mask. Images obtained by exposing the fabricated mask can include U1 and U2. U1 can include the image of A1 and can be used to fabricate modules of A1, A2, A3, and A4. U2 can include the image of B1 and can be used to fabricate modules of B1, B2, B3, B4, B5, and B6.

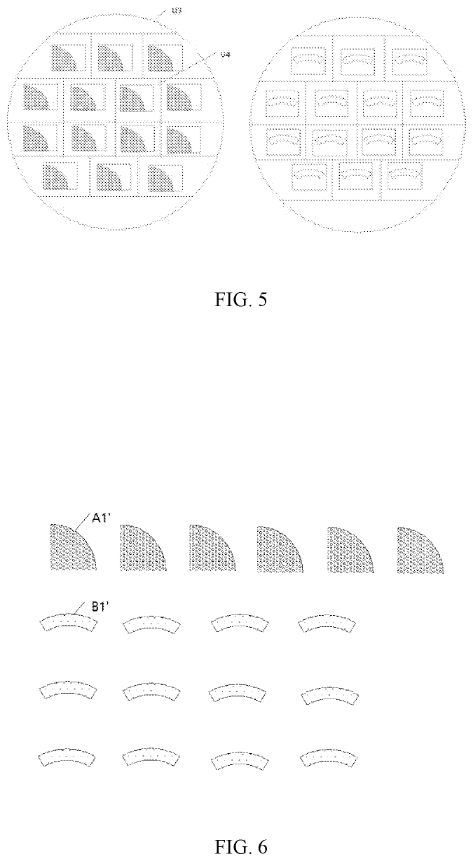

In some embodiments, as shown in FIG. 5, a fabricated mask corresponding to U1 is arranged on the step-scanning lithography system. A working platform of the step-scanning lithography system placed with a pre-processed substrate is moved to an initial position for exposure to obtain exposure area U1 corresponding to the image of A1. The mobile platform is then moved to a next exposure position for exposure. The above process can be repeated to finish the exposure of the mask on the substrate. Then the system switches to the exposure mask corresponding to U2, and the substrate is changed for step exposure to complete the exposure of the current mask on the substrate. According to different quantity requirements of the sub-modules, the masks can be changed during the exposure process on the same substrate to form images of a plurality of sub-modules on one wafer.

In some embodiments, as shown in FIG. 6, after the image transfer, subsequent processes such as developing and etching are performed on the substrate to obtain a plurality of images of the sub-modules for slicing. The submodules are cut from the substrate to obtain the sub-modules for splicing.

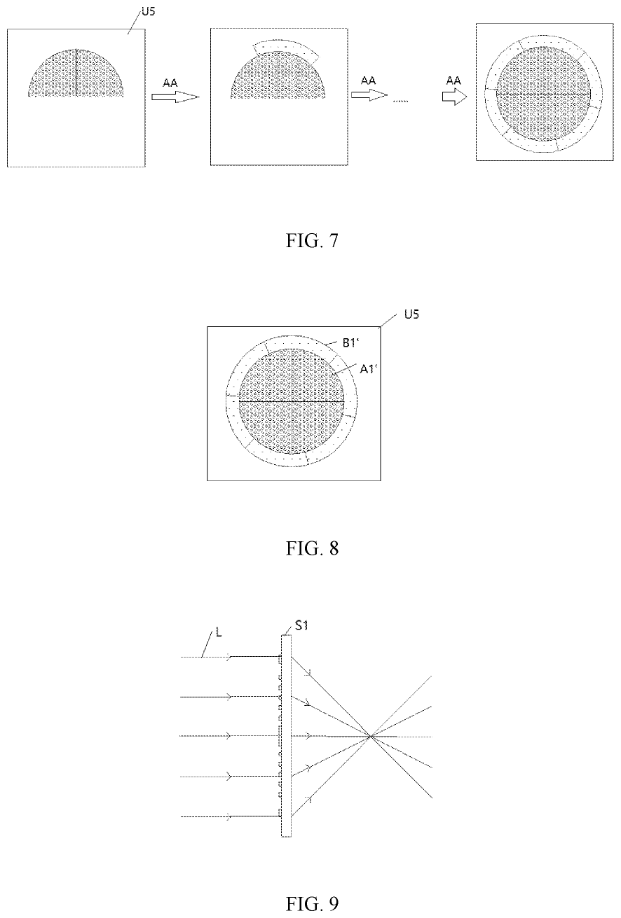

In some embodiments, as shown in FIG. 7, AA is performed on two neighboring sub-modules obtained by cutting, on a substrate U5 according to the image design. After an optimal MTF is obtained by performing AA, the two sub-modules are spliced. Then, AA is performed on a next neighboring sub-module and the spliced module. After an optimal MTF is obtained by performing AA, the two modules are spliced together. The above process can be repeated until the whole metasurface lens is obtained on the substrate.

In some other embodiments, as shown in FIG. 2, circular area S is a designed metasurface lens image area. Circular area S is larger than an image area fabricated by a single time of imprinting of a high-resolution nano-imprinting system.

As shown in FIG. 3, the image is divided into the plurality of sub-modules smaller than a single-time imprinting area of the nano-imprinting system through software processing. A1, A2, A3, and A4 can include a same image. B1, B2, B3, B4, B5, and B6 can include a same image.

As shown in FIG. 4, a lithography mask is fabricated by directly writing using electron beam lithography or machining according to a software processing result. If some sub-modules are identical, only one mask needs to be fabricated for these identical sub-modules. According to sizes of the sub-modules, images of a plurality of sub-modules can be designed on the same mask. Images obtained by exposing the fabricated mask can include U1 and U2. U1 can include the image of A1 and can be used to fabricate modules of A1, A2, A3, and A4. U2 can include the image of B1 and can be used to fabricate modules of B1, B2, B3, B4, B5, and B6.

As shown in FIG. 5, a large-scale imprinting template U1B is fabricated using a U1 imprinting mask. A plurality of A1 images can be imprinted at one time. A large-scale imprinting template U2B is fabricated by using a U2 imprinting mask. A plurality of A1 images can be imprinted at one time. The mask corresponding to the fabricated U1B can be arranged at the nano-imprinting system. The nano-imprinting working platform placed with a pre-processed substrate is moved to an initial position to perform the imprinting to obtain imprinting area U1. Corresponding to image A1, a predicted quantity of A1 modules can be obtained. The mask of U2B is switched, and the substrate is changed for imprinting to complete the imprinting of the current mask on the substrate. According to different quantity requirements of the sub-modules, the imprinting can be performed by integrating a plurality of small templates on the same large template. Thus, a plurality of sub-module images can be imprinted on one wafer.

As shown in FIG. 6, after the image transfer, the subsequent processes such as developing and etching are performed on the substrate to obtain the plurality of images of the sub-modules for splicing. The sub-modules are cut from the substrate to obtain the subs-modules for splicing.

As shown in FIG. 7, AA is performed on two neighboring sub-modules that are obtained by cutting, on a substrate U5 according to the image design. After an optimal MTF is obtained by performing AA, the two sub-modules are spliced. Then, AA is performed on a next neighboring sub-module and the spliced module. After an optimal MTF is obtained by performing AA, the two modules are spliced together. The above process can be repeated until the complete metasurface lens is obtained on the substrate.

In the method for fabricating large-scale metasurface lens based on AA process, as compared with other exposure manners for large-scale metasurface lens image, the manners described above can reduce the cost and improve the efficiency. Moreover, AA performed during splicing can effectively reduce the assembly tolerance of the whole lens. The manner above can be easily applied, which has a simple fabrication process, achieves fabrication of large-scale metasurface lens structure at a low cost, and effectively reduces the assembly tolerance during the assembly. Thus, a new low-cost large-scale fabrication technology is provided for the large-scale metasurface lens structure.

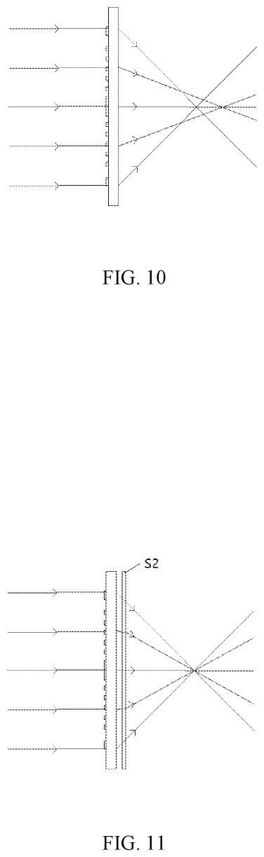

FIG. 2 to FIG. 6 and FIG. 8 to FIG. 11 illustrate a method for fabricating large-scale metasurface lens based on a one time programmable (OTP) technology according to some embodiments of the present disclosure. Due to the influences of various factors, camera assemblies can have certain differences in aberration and shading. If a same set of parameters are used to calibrate the lens aberration and lens shading, the effect can often be unsatisfactory. If lens shading calibration is performed on each assembly when leaving the factory, and the calibration parameters are burnt into the OTP, the parameters can just be read from the OTP and applied to the image when the image is displayed at the user end. The imaging effect can be very consistent. A compensation lens can be fabricated for the assembly after the calibration. The compensation lens and the lens can be fabricated as an assembly to achieve the compensation. The fabrication method based on OTP is described below with reference to FIG. 2 to FIG. 6 and FIG. 8 to FIG. 11, in which process eleven to process eighteen are the same as process one to process eight of the fabrication method based on AA.

At process eleven, image processing is performed on a design file of the large-scale metasurface lens pattern to extract areas with the same pattern, and divide the pattern into a plurality of sub-modules smaller than or equal to 26 mm×33 mm. Only one photolithography mask or nano-imprinting mask is fabricated for repeated sub-modules. Image transfer masks are fabricated for other non-repeated pattern areas, respectively. One or more masks can be obtained at process eleven.

At process twelve, a mobile platform first moves to an initial image transfer position, and the mask corresponding to the current position fabricated in Process eleven is used to perform exposure or imprinting. Imprinting is also image transfer. The software for splitting the exposure image can be developed by using suitable programming tool or pattern processing tool.

At process thirteen, the mobile platform repeats process twelve at a next image transfer position to perform the image transfer at this position.

At process fourteen, process thirteen is repeated until the image transfer of the pattern of the mask is completed for the whole substrate.

At process fifteen, the mask is switched or a mask pattern at a different position in the same mask is used, the mobile platform moves to a next exposure position to repeat process twelve to process fourteen to complete the image transfer of the mask pattern for the whole substrate.

At process sixteen, process fifteen is repeated until the image transfer of all the sub-modules for slicing is completed.

At process seventeen, subsequent processes such as developing and etching are performed on the substrate on which the whole image transfer is completed to obtain sub-modules of the large-scale metasurface lens structure.

At process eighteen, the sub-modules of the metasurface lens on the substrate are cut to obtain a plurality of individual sub-modules.

At process nineteen, the sub-modules that are cut are spliced together according to the image design to obtain the complete large-scale metasurface lens.

At process twenty, the aberration of the metasurface lens is measured, and the OTP compensation lens is designed according to the measured aberration to compensate the aberration of the metasurface lens.

At process twenty-one, the metasurface lens and the OTP compensation lens are combined to form the assembly.

The present disclosure is further explained in connection with the accompanying drawings and the method for fabricating large-scale metasurface lens based on the OTP technology. In FIG. 8, U5 is the substrate for splicing (“splicing substrate”). FIG. 9 shows a theoretical effect that should have been achieved by light of light source L after being modulated by the metasurface lens. Si is a side surface of metasurface lens S. The light source can be visible light, infrared light, or any light that the metasurface lens is designed to modulate. A modulation effect is not limited to the examples shown in the accompanying drawings.

In some embodiments, as shown in FIG. 2, circular area S is a designed metasurface lens image area. Circular area S is larger than an image area fabricated by a single time of imprinting of a high-resolution nano-imprinting system.

As shown in FIG. 3, the image is divided into the plurality of sub-modules smaller than a single-time imprinting area of the nano-imprinting system through the software processing. A1, A2, A3, and A4 can include a same image. B1, B2, B3, B4, B5, and B6 can include a same image.

As shown in FIG. 4, a lithography mask is fabricated by directly writing using electron beam lithography or machining according to a software processing result. If some sub-modules are identical, only one mask needs to be fabricated for these identical sub-modules. According to sizes of the sub-modules, images of a plurality of sub-modules can be designed on the same mask. Images obtained by exposing the fabricated mask can include U1 and U2. U1 can include the image of A1 and can be used to fabricate modules of A1, A2, A3, and A4. U2 can include the image of B1 and can be used to fabricate modules of B1, B2, B3, B4, B5, and B6.

As shown in FIG. 5, a fabricated mask corresponding to U1 is arranged on the step-scanning lithography system. A working platform of the step-scanning lithography system placed with a pre-processed substrate is moved to an initial position for exposure to obtain exposure area U1 corresponding to the image of A1. The mobile platform is then moved to a next exposure position for exposure. The above process can be repeated to finish the exposure of the mask on the substrate. Then the system switches to the exposure mask corresponding to U2, and the substrate is changed for step exposure to complete the exposure of the current mask on the substrate. According to different quantity requirements of the sub-modules, the masks can be changed during the exposure process on the same substrate to form images of a plurality of sub-modules on one wafer.

As shown in FIG. 6, after the image transfer, subsequent processes such as developing and etching are performed on the substrate to obtain a plurality of images of the sub-modules for slicing. The submodules are cut from the substrate to obtain the sub-modules for splicing.

As shown in FIG. 8, the sub-modules that are obtained by cutting are spliced together on the splicing substrate according to the image design to obtain the complete metasurface lens.

The parameters obtained after the aberration and lens shading are calibrated can be recorded for the obtained metasurface lens and can be applied to the image when the image is displayed. In some other embodiments, as shown in FIG. 11, a one-time compensation lens is fabricated. The compensation lens and the metasurface lens can be formed into an assembly to obtain a complete compensated metasurface lens fabricated by splicing.

In some other embodiments, as shown in FIG. 2, circular area S is a designed metasurface lens image area. Circular area S is greater than an image area fabricated by a single time of imprinting of a high-resolution nano-imprinting system.

As shown in FIG. 3, the image is divided into the plurality of sub-modules smaller than a single-time imprinting area of the nano-imprinting system through software processing. A1, A2, A3, and A4 can include a same image. B1, B2, B3, B4, B5, and B6 can include a same image.

As shown in FIG. 4, a lithography mask is fabricated by directly writing using electron beam lithography or machining according to a software processing result. If some sub-modules are identical, only one mask needs to be fabricated for these identical sub-modules. According to sizes of the sub-modules, images of the plurality of sub-modules can be designed on the same mask. Images obtained by exposing the fabricated mask can include U1 and U2. U1 can include the image of A1 and can be used to fabricate modules of A1, A2, A3, and A4. U2 can include the image of B1 and can be used to fabricate modules of B1, B2, B3, B4, B5, and B6.

As shown in FIG. 5, a fabricated mask corresponding to U1 is arranged on the nano-imprinting system. A working platform of the nano-imprinting system placed with a pre-processed substrate is moved to an initial position. The imprinting is performed to obtain an imprinting area U1 corresponding to the image of A1. The mobile platform is then moved to a next imprinting position for imprinting. The above process can be repeated to finish the imprinting of the current mask on the substrate to obtain a predicted quantity of A1 modules. Then the system switches to the exposure mask corresponding to U2, and the substrate is changed for imprinting to complete the imprinting of the current mask on the substrate. According to different quantity requirements of the sub-modules, the masks can be changed during the exposure process on the same substrate to form images of the plurality of sub-modules on one wafer.

As shown in FIG. 6, after the image transfer, subsequent processes such as developing and etching are performed on the substrate to obtain a plurality of images of the sub-modules for slicing. The submodules are cut from the substrate to obtain the sub-modules for splicing.

As shown in FIG. 8, the sub-modules that are obtained by cutting are spliced together on the splicing substrate according to the image design to obtain the complete metasurface lens.

The parameters obtained after the aberration and lens shading are calibrated can be recorded for the obtained metasurface lens and can be applied to the image when the image is displayed. In some other embodiments, as shown in FIG. 11, a one-time compensation lens is fabricated. The compensation lens and the metasurface lens can be formed into an assembly to obtain a complete compensated metasurface lens fabricated by splicing.

In the method for fabricating large-scale metasurface lens based on the OTP technology, the above fabrication processes are simple, which achieves the fabrication of the large-scale metasurface lens structure at low cost and compensates the performance reduction of the metasurface lens caused by splicing tolerance. Thus, A new low-cost large-scale fabrication technology can be provided for large-scale metasurface lens structure.

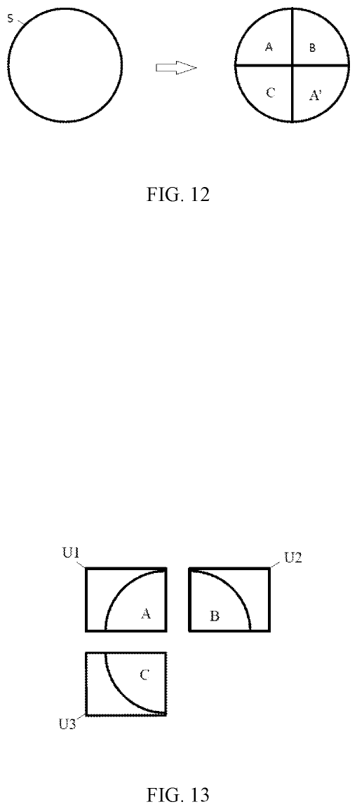

FIG. 12 to FIG. 15 illustrate a method for fabricating large-scale metasurface lens by splicing according to some embodiments of the present disclosure. Circle S in FIG. 12 is a pattern area, which can be divided into four areas: A, A′, B, and C. A and A′ areas have an identical pattern, and are symmetrical to each other about a pattern center. A, B, and C have different patterns. As shown in FIG. 13, three exposure masks used for step-scanning lithography or nano-imprinting masks, U1, U2, and U3, are fabricated. Image transfer areas corresponding to the masks each have a size of 26 mm×33 mm and include patterns A, B, and C, respectively. As shown in FIG. 15, U5 is a wafer for image transfer. The wafer can be a silicon wafer, a glass wafer, or any substrate for fabricating metasurface lens. U6 is an exposure area on the wafer. The method can include the following processes.

At process twenty-two, image processing is performed on a design file of the large-scale metasurface lens pattern to extract areas with the same pattern, and divide the pattern into a plurality of sub-modules smaller than or equal to 26 mm×33 mm. Only one photolithography mask or nano-imprinting mask is fabricated for repeated sub-modules. Image transfer masks are fabricated for other non-repeated pattern areas, respectively. One or more masks can be obtained at process twenty-one.

At process twenty-three, a mobile platform first moves to an initial image transfer position, and the mask corresponding to the current position fabricated in process twenty-one is used to perform exposure or imprinting. Imprinting is also image transfer. The software for splitting the exposure image can be developed by using suitable programming tool or pattern processing tool.

At process twenty-four, if the sub-modules in process twenty-three have repeated areas in the whole pattern, the mobile platform moves to a next image transfer position. If the pattern at the position has an angle deviation from the pattern at the last exposure position, the working platform is rotated to cause the sub-module to match the pattern at the exposure position to complete the image transfer at the position.

At process twenty-five, process twenty-four is repeated until the pattern of the mask is transferred to the whole substrate.

At process twenty-six, the mask is switched or a mask pattern at a different position in the same mask is used, the mobile platform moves to a next exposure position to repeat process twenty-three to process twenty-five to complete the image transfer of the mask pattern for the whole substrate.

At process twenty-seven, process twenty-six is repeated until the image transfer of all the sub-modules for slicing is completed.

At process twenty-eight, subsequent processes such as developing and etching are performed on the substrate on which the whole image transfer is completed to obtain sub-modules of the large-scale metasurface lens structure.

In connection with the accompanying drawings and the method for fabricating large-scale metasurface lens by splicing, the present disclosure is further described below.

In some embodiments, as shown in FIG. 12, circle S with a diameter of 50 mm is a designed pattern area of the metasurface lens. In the present disclosure, the designed metasurface lens pattern S can be first processed by software to be divided into four areas A, A′, B, and C. A and A′ areas have repeated patterns, and are symmetrical to each other about a pattern center. A, B, and C have different patterns. The patterns each have a size smaller than or equal to 26 mm 33 mm.

As shown in FIG. 13, a lithography mask to be used by the step-scanning lithography system is fabricated for each of the divided pattern areas by performing directly writing using electron beam lithography or machining. Only one mask needs to be fabricated for repeated image areas. Three exposure masks for the step-scanning lithography system are fabricated. The exposure is performed using the fabricated masks to obtain corresponding patterns U1, U2, and U3. Exposure fields of view can each be 26 mm×33 mm and include patterns A, B, and C, respectively.

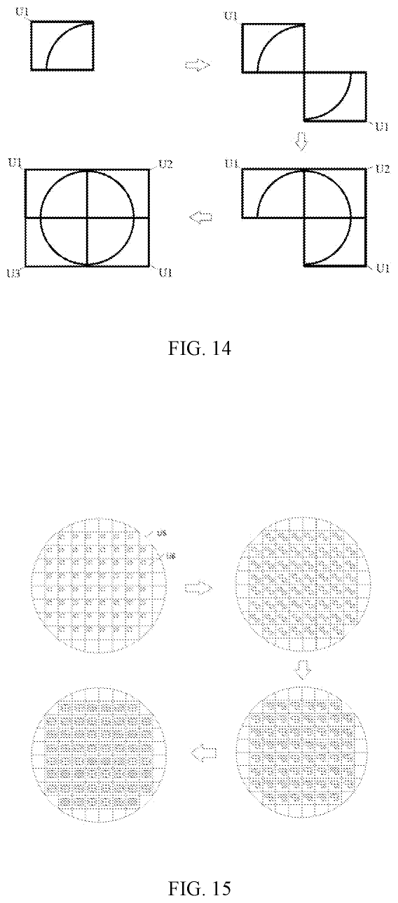

As shown in FIG. 14, the mask corresponding to U1 is first installed. The working platform of the step-scanning lithography system placed with the pre-processed substrate is moved to the initial position for exposure to obtain exposure area U1 corresponding to pattern A. The mobile platform is then moved to an exposure position for pattern A′ and rotated for 180°, and exposure is performed to obtain pattern A′. The system switches to the mask corresponding to U2. The mobile platform is moved to an exposure position for pattern B and exposure is performed to obtain exposure area U2 corresponding to pattern B. The system switches to the mask corresponding to U3. The mobile platform is moved to an exposure position for pattern C for exposure.

After a plurality of exposures and splicing processes, subsequent processes such as developing and etching can be performed on the substrate to obtain a plurality of complete patterns S.

In some embodiments, as shown in FIG. 12, circle S with a diameter of 50 mm is a designed pattern area of the metasurface lens. In the present disclosure, the designed metasurface lens pattern S can be firstly processed by software to be divided into four areas: A, A′, B, and C. A and A′ areas have repeated patterns and are symmetrical to each other about a pattern center. A, B, and C have different patterns. The patterns each have a size smaller than or equal to 26 mm×33 mm.

As shown in FIG. 13, a lithography mask to be used by the step-scanning lithography system is fabricated for each of the divided pattern areas by performing direct writing using electron beam lithography or machining. Only one mask needs to be fabricated for repeated image areas. Three exposure masks for the step-scanning lithography system are fabricated. The exposure is performed using the fabricated masks to obtain corresponding patterns U1, U2, and U3. Exposure fields of views can each be 26 mm×33 mm and include patterns A, B, and C, respectively.

As shown in FIG. 14, the mask corresponding to U1 is first installed. The working platform of the step-scanning lithography system placed with the pre-processed substrate is moved to the initial position for imprinting to obtain pattern area U1 corresponding to pattern A. The mobile platform is then moved to a position for pattern A′ and rotated for 180°, and imprinting is performed to obtain pattern A′. The system switched to the template corresponding to U2. The mobile platform is moved to a position of pattern B for imprinting to obtain pattern area U2 corresponding to pattern B. The system switches to the template corresponding to U3. The mobile platform is moved to a position for pattern C for imprinting.

After a plurality of times of imprinting, the subsequent processes of developing and etching can be performed on the substrate to obtain the plurality of whole patterns S.

Based on the above, in the present disclosure, with the lithography or nano-imprinting fabrication process in a splicing mode, the repeated pattern unit in the layout can be transferred to the substrate after a plurality of times of image transfer processes to define the repeated pattern. An area of the fabricated metasurface lens is not limited to a size of a single exposure or imprinting area. The same patterns with any angle can be exposed or imprinted using the same mask by rotating the working platform for a certain angle.

In the large-scale metasurface lens fabrication method by splicing, the above fabrication processes are simple, which can achieve a low-cost fabrication of large-scale metasurface lens structure and hence provide a new low-cost mass fabrication technology for large-scale metasurface lens structure. Further, the spliced complete large-scale metasurface lens pattern can be used to fabricate a mother plate used for nano-imprinting. Nano-imprinting masks obtained by duplicating the mother plate can be used to massively and efficiently fabricate metasurface lenses with the pattern design in a large amount.

In embodiments of the present disclosure, the metasurface lens image can be obtained. The metasurface lens image can be divided according to the preset size to obtain at least two sub-images and one or more masks each corresponding to one or more of the sub-images. The image transfer can be performed on the first wafer through the at least two sub-images and the one or more masks corresponding to the sub-images to obtain the second wafer with the metasurface lens image. Fabrication processing can be performed on the second wafer to obtain the metasurface lens. The efficiency can be improved and the cost can be reduced, while still meeting the optical performance requirement.

The present disclosure further provides a metasurface lens obtained by the fabrication method consistent with the disclosure, such as any of the above example fabrication methods.

In the specification, specific details are provided. However, embodiments of the present disclosure can be implemented without these specific details. In some embodiments, well-known methods, structures, and techniques are not shown in detail to not obscure an understanding of the specification.

Similarly, to simplify embodiments of the present disclosure and facilitate understanding one or more of aspects of the present disclosure, features of embodiments of the present disclosure can be grouped in a single embodiment, drawing, or description.

In addition, those skilled in the art can understand that although some embodiments include some features included in other embodiments rather than other features, features of different embodiments can be combined to form different embodiments in the scope of the present disclosure.

The above embodiments illustrate rather than limit the present disclosure. The term “a” or “an” before an element does not exclude the presence of a plurality of such elements. Embodiments of the present disclosure can be implemented by hardware including several different elements and a suitably programmed computer. The terms first, second, and third do not indicate any sequence. The terms can be interpreted as names. Processes of embodiments of the present disclosure should not be construed as limiting the execution order unless otherwise specified.

What is claimed is:

1. A metasurface lens fabrication method comprising:
obtaining a metasurface lens image;
dividing the metasurface lens image to obtain at least two sub-images and one or more masks each corresponding to one or more of the at least two sub-images;
performing image transfer on a first wafer through the at least two sub-images and the one or more masks to obtain a second wafer with the metasurface lens image; and
performing lens fabrication processing on the second wafer to obtain the metasurface lens.

2. The method of claim 1, wherein dividing the metasurface lens image to obtain the at least two sub-images and the one or more masks includes:
dividing the metasurface lens image to obtain the at least two sub-images; and
fabricating the one or more masks according to the at least two sub-images.

3. The method of claim 2, wherein:
the at least two sub-images include at least two identical sub-images having a same image; and
fabricating the one or more masks according to the at least two sub-images includes fabricating one mask according to the same image as a mask corresponding to the at least two identical sub-images.

4. The method of claim 1, wherein performing image transfer on the first wafer includes performing image transfer for the at least two identical sub-images according to a preset order through the one mask that corresponds to the at least two identical sub-images.

5. The method of claim 4, wherein:
an angle deviation exists between a first sub-image and a second sub-image of the at least two identical sub-images; and
performing image transfer for the at least two identical sub-images includes rotating the one mask corresponding to the at least two identical sub-images or the first wafer by an angle corresponding to the angle deviation after image transfer is performed for the first sub-image and before image transfer is performed for the second sub-image.

6. The method of claim 2, wherein performing image transfer on the first wafer to obtain the second wafer includes:
arranging the one or more masks according to the metasurface lens image to obtain an arranged image mask; and
performing image transfer on the first wafer according to the arranged image mask group to obtain the second wafer.

7. The method of claim 1, wherein performing the lens fabrication processing on the second wafer to obtain the metasurface lens includes:
performing developing, etching, cleaning, and coating on the second wafer to obtain a third wafer;
dividing the third wafer obtain at least two sub-wafers; and
splicing the at least two sub-wafers according to the metasurface lens image to obtain the metasurface lens.

8. The method of claim 7, wherein splicing the at least two sub-wafers includes:
determining an optimal modulation transfer function of every two neighboring sub-wafers of the at least two sub-wafers through active alignment (AA) according to the metasurface lens image; and
splicing the at least two sub-wafers according to the optimal modulation transfer function to obtain the metasurface lens.

9. The method of claim 7, further comprising, after obtaining the at least two sub-wafers:
splicing the at least two sub-wafers according to the metasurface lens image to obtain a spliced transition lens;
measuring an aberration of the transition lens and designing a compensation lens according to the aberration; and
combining the compensation lens and the transition lens to obtain the metasurface lens.

10. A metasurface lens fabricated by the method of claim 1.
